(19) United States
(12) Patent Application Publication
(10) Pub. No.: US 2008/0095207 A1
(43) Pub. Date: Apr. 24, 2008

(54) Process for precisely forming diffraction grating light-emitting device and a laser diode providing the same

(76) Inventor: Toshio NOMAGUCHI, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/907,408

(22) Filed: Oct. 11, 2007

(30) Foreign Application Priority Data
Oct. 12, 2006 (JP) 2006-278293

(51) Int. Cl. H01S 5/00; H01L 21/00

(52) U.S. Cl. 372/50.11; 438/32; 257/E21.001

(57) ABSTRACT

The present invention provides a process to form the diffraction grating involved in the DFB-LD precisely, and a DFB-LD device with precisely formed diffraction grating. The DFB-LD of the invention provides a monitoring layer and another semiconductor layer on the monitoring layer as the diffraction grating. The other layer contains elements except for arsenic or has a composition different from that of the monitoring layer. The diffraction grating may be formed by the dry-etching such as the RIE (Reactive Ion Etching) as detecting a luminescence from arsenic. The process may detect the exposure of the monitoring layer and the termination thereof by the luminescence from arsenic.

### BACKGROUND OF THE INVENTION

1. Field of the Invention

The present invention relates to a process to form a diffraction grating in a laser diode precisely and a laser diode having such a diffraction grating.

2. Related Prior Art

A distributed feedback laser diode (hereafter denoted as DFB-LD) or a laser diode with a distributed Bragg reflector (hereafter denoted as DBR-LD) provides an diffraction grating where a refractive index periodically varies. The emission wavelength of such DFB-LD or DBR-LD is primarily determined by this period in the diffraction grating, and such devices are widely applied to the signal sources in the optical communication because of their stable operation with a quite narrow spectral width.

Japanese Patent Application published as JP-2003-075619A has disclosed a method to form the diffraction grating for the DFB-LD. The method disclosed therein first forms a striped pattern in the mask layer provided on the semiconductor material by the two-beam interfering exposure technique or by the electron beam exposure technique. Next, the semiconductor material is etched as the striped pattern as an etching mask to form an undulation structure of the semiconductor material. The mask layer is generally a photoresist or an insulating film made of silicon oxide (SiO₂).

The height, or the depth, of the undulation in the diffraction grating strongly affects the diffraction efficiency, and the controllability and the monochromatism of the wavelength, namely, spectral width thereof. Accordingly, to precisely control the height/depth of the undulation becomes important. Generally, the undulation of the semiconductor material may be formed by the etching, either the dry etching or the wet etching; the Japanese Patent mentioned above has disclosed a method using the dry etching. Specifically, the Japanese Patent has disclosed a method to control the height/depth of the undulation, in which the dry etching is carried out by an insulating film such as SiO₂ as the etching mask and the etching is continued until this insulating mask fully disappears.

Generally, the height/depth of the undulation in the diffraction grating may be controlled by; (1) estimating the etching rate of the material constituting the undulation in advance to the practical process, and (2) adjusting the etching time during the practical process. However, this process has been unable to adjust the precise shape of the undulation, and accordingly has lacked in the reproducibility of the process.

The coupling coefficient of the diffraction grating in the DFB-LD, which is often called as the K co-efficient, is one of the important physical parameters, and this K-coefficient strongly depends on the height/depth of the undulation. Thus, the conventional process to form the diffraction grating by adjusting the etching time based on the pre-measured etching rate has caused a scattering in the K-coefficient, accordingly, the performance of the DFB-LD. When the K-coefficient is small due to a shallow and moderate undulation, the DFB-LD tends to show a multi-mode oscillation, while, the deep undulation causes a large K-coefficient to bring an unstable operation at a large current injection mode due to, what is called, the hole burning effect.

The method disclosed in the Japanese Patent described above, the process continues to etch the semiconductor material until the insulating mask layer made of SiO₂ disappears. However, this process is substantially same as the conventional method in a meaning that the process is necessary to measure the etching rate of the SiO₂ mask in advance to the practical etching. Moreover, it is quite hard to detect the point in the time when the mask SiO₂ fully disappears.

Accordingly, conventional processes to form the diffraction grating are inherently unable to secure the controllability and the reproducibility of the shape of the undulation, which results in the scattering of the K-coefficient and the performance of the DFB-LD.

### SUMMARY OF THE INVENTION

One aspect of the invention relates to a process to form a diffraction grating made of semiconductor materials within a semiconductor optical device. The process includes steps of: (a) sequentially growing at least one monitoring layer and at least one semiconductor layer; (b) forming an etching mask on the semiconductor layer; and (c) dry-etching the semiconductor layer and the monitoring layer sequentially. In the process of the invention, the monitoring layer is made of a group III-V compound semiconductor material containing an element, while, the semiconductor layer is also made of a group III-B compound semiconductor material not containing the element, and, the step of dry-etching is carried out as monitoring a luminescence of the element to stop the dry-etching.

The monitoring layer may be made of InP, while, the semiconductor layer may be made of InGaAsP, and the dry-etching may be carried out as monitoring the luminescence from arsenic (As) or gallium (Ga), or both of arsenic (As) and gallium (Ga).

Furthermore, the monitoring layer may include a plurality of first compound semiconductor layers with a first composition and the semiconductor layer may include a plurality of second compound semiconductor layers with a second composition, where the first semiconductor layers and the second semiconductor layers are grown alternately to each other. The first composition contains an element, while, the second composition does not contain the element. And the process for dry-etching may be carried out as monitoring the luminescence of the element. According to the process of the present invention, the dry-etching may be precisely terminated due to the existence of the monitoring layer.

Another aspect of the present invention relates to a structure of the DFB-LD, in particular, the structure of the diffraction grating. The diffraction grating of the present invention comprises a plurality of mesas with a specific period and each mesa includes a stack of a monitoring layer and a semiconductor layer. The semiconductor layer is made of a first compound semiconductor material with a first composition containing an element, while, the monitoring layer is made of another compound semiconductor material with a second composition not containing the element. Because of the existence of the monitoring layer, the height, or the depth, of each mesa may be precisely controlled, which suppresses the scattering of the K co-efficient, accordingly, the performance of the DFB-LD.

### BRIEF DESCRIPTION OF DRAWINGS

FIG. 1 is a perspective view, partially illustrating a cross section thereof, of the DFB-LD according to an embodiment of the invention;

FIG. 2 is a cross section, which is taken along the line A-A in FIG. 1, of the DFB-LD of the embodiment shown in FIG. 1;

FIGS. 3A to 3D show process steps to form the DFB-LD of the present invention;

FIGS. 4A to 4C show process steps, subsequent to the step shown in FIG. 3D, to form the DFB-LD of the present invention;

FIG. 5 illustrates a behavior of the luminescence from arsenic during the etching;

FIGS. 6A and 6B show process steps for another DFB-LD with a modified structure in the monitoring layers and the upper SCH layers; and

FIG. 7 illustrates a behavior of the luminescence from arsenic during the etching for the structure shown in FIGS. 6A and 6B.

### DETAILED DESCRIPTION OF THE INVENTION

Next, preferred embodiments of the present invention will be described as referring to accompanying drawings. In the description of drawings, the same symbols or the same numerals will refer to the same elements without overlapping explanations.

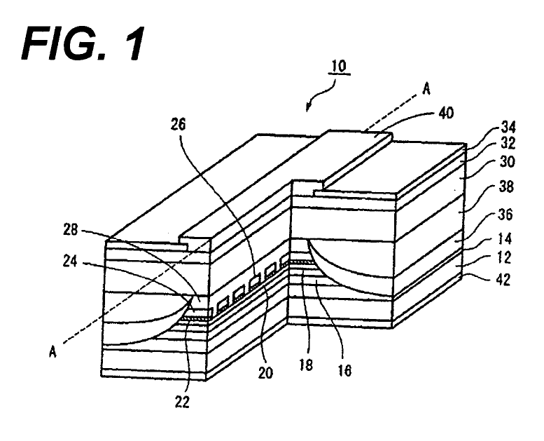

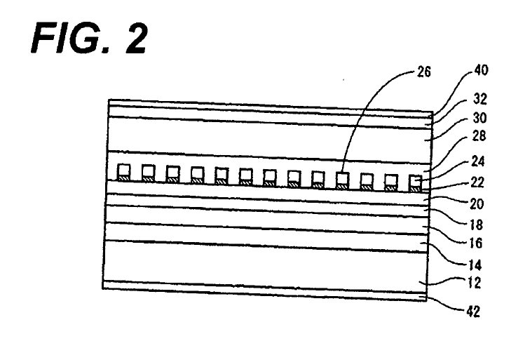

FIG. 1 is a perspective view, which is partially cut to show the inside layer structure, of a DFB-LD according to an embodiment of the present invention, and FIG. 2 is a cross section of the DFB-LD taken along the line A-A in FIG. 1. The DFB-LD 10 of the present invention provides, on the n-type InP substrate, an n-type InP buffer layer 14, a lower SCH layer 16, an MQW active layer 18, a first upper SCH layer 20, a second upper SCH layer 24, an diffraction grating 26, and a first p-type InP cladding layer 28. The p-type cladding layer 28 buries the diffraction grating 26.

Among these layers, the lower SCH layer 16, the first upper SCH layer 20 and the second upper SCH layer 24 are made of GaInAsP with the band gap wavelength of 1.1 μm. The MQW active layer 18 comprises of 10 GaInAsP layers each having a thickness of 5 nm and a band gap wavelength of 1.35 μm and 11 GaInAsP layers each having a thickness of 10 nm and a band gap wavelength of 1.2 μm. These two types of GaInAsP layers are alternately stacked to each other to form the multiple quantum well (MQW) structure, and the outermost layers are the second type of GaInAsP layer with the band gap wavelength of 1.2 μm. The configurations of these two types of InGaAsP layers show about 1300 nm in the peak wavelength in the gain of the MQW structure. Here, the peak wavelength in the gain of the MQW structure corresponds to the effective energy bandgap of the MQW structure. The second upper SCH layer 24 and the monitoring layer 22, which is stacked beneath the second upper SCH layer 24 and is made of p-type InP, constitute a periodic stripe for the diffraction grating 26. The diffraction grating 26 is completed by burying between the mesas with the first upper cladding layer 28 made of a p-type InP.

The functional layers, which include the first upper cladding layer 28, the diffraction grating 26, the first upper SCH layer 20, the MQW active layer 18, the lower SCH layer 16 and the upper portion of the n-type buffer layer 14, shapes in a mesa structure. Both sides of the mesa structure are buried with the current blocking portion including the p-type InP layer 36 and the n-type InP layer 38. On the first upper cladding layer 28 and on the current blocking portion are provided with the p-type InGaAs contact layer 32. The p-type electrode 40 comes in contact to this p-type InGaAs contact layer 32, while, the n-type electrode 42 comes in contact to the back surface of the n-type InP substrate 12. Typically, the p-type electrode comprises a stacked metal of titanium/platinum/gold (Ti/Pt/Au), while, the n-type electrode is made of eutectic alloy of AuGeNi.

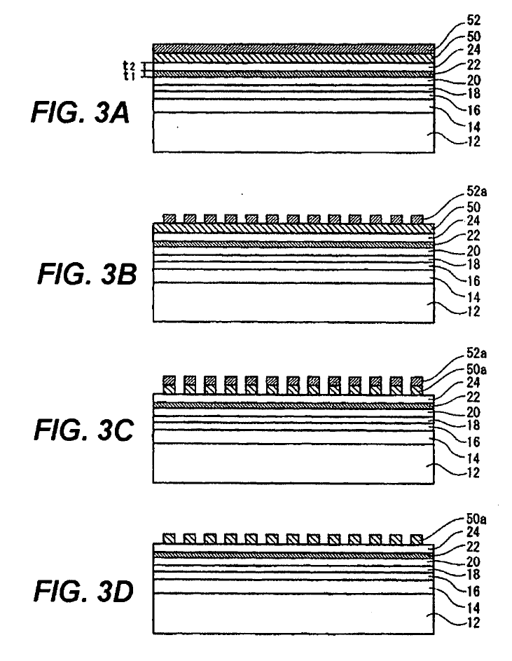

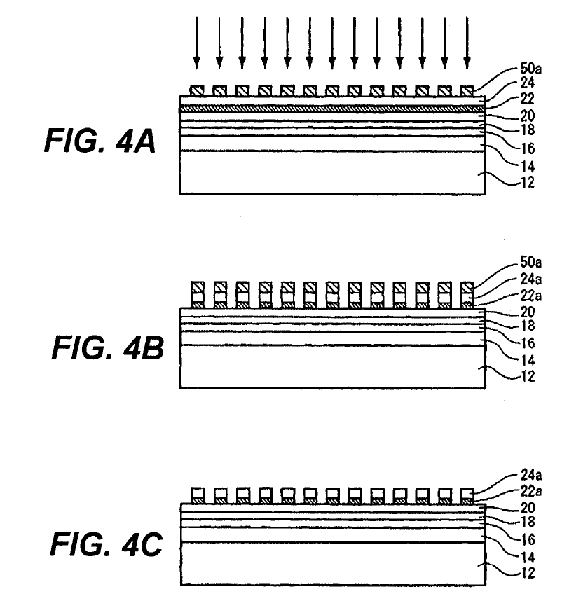

Next, a process to form the DFB-LD shown in FIGS. 1 and 2 will be described as referring to FIGS. 3 and 4, which are cross sectional views showing the process for the DFB-LD of the present invention.

First, a conventional organic-metal vapor phase epitaxy (OMVPE) epitaxially grows, on the n-type InP substrate, a series of semiconductor layers including; (a) the n-type InP buffer layer 14, which becomes the lower cladding layer, (b) the lower SCH layer 16 with the band gap wavelength of 1.1 μm, (c) the MQW active layer 18, (d) the first upper SCH layer 20 made of GaInAsP with the band gap wavelength of 1.1 μm, (e) the monitoring layer 22 made of InP with a thickness t1, for instance 10 nm, and (f) the second upper SCH layer made of GaInAsP with the band gap wavelength of 1.1 μm and the thickness of t2, for instance 30 nm. The total thickness of the monitoring layer 22 and the second upper SCH layer 24, t1+t2, is preferably equal to the height or the depth of the undulation of the diffraction grating. The height/depth of the mesa in the diffraction grating is primarily determined by the total thickness=(t1+t2) of respective layers. The layer configuration of the invention provides the monitoring layer 22 in the lower side; accordingly, the height of the undulation of the diffraction grating may be controlled with good reproducibility. Moreover, the monitoring layer 22 under the second upper SCH layer 24 may be thin enough to inject carriers into the MQW active layer 18 from the upper electrode 40 therethrough.

The MQW active layer 18, as described above, has the MQW structure containing well layers made of GaInAsP with the band gap wavelength of 1.35 μm and barrier layers made of GaInAsP with the band gap wavelength of 1.2 μm.

Next, on the second upper SCH layer 24 is formed with double layers of an insulating film 50 and a photoresist film 52. The insulating film 50 may be a silicon die-oxide (SiO₂) or a silicon nitride (SiN). The electron beam exposures the photoresist to form periodic patterns 52a with a period thereof about 200 nm for the diffraction grating. The etching of the insulating film 50 by the patterned photoresist 52a as an etching mask leaves a periodic pattern 50a in the insulating film 50, which becomes the etching mask for the semiconductor layers under the film 50. After ashing the photoresist, the reactive ion etching (RIE) using a mixed gas of methane (CH₄) and hydrogen (H₂) removes the second upper SCH layer 24 and the monitoring layer 22 made of p-type InP.

An exemplary condition of the RIE was as follows:

RIE Conditions

| gas flowing rate | CH₄/H₂ = 1:1 | |
|---|---|---|
| pressure | 2.0 | Pa |
| microwave power | 100 | W |

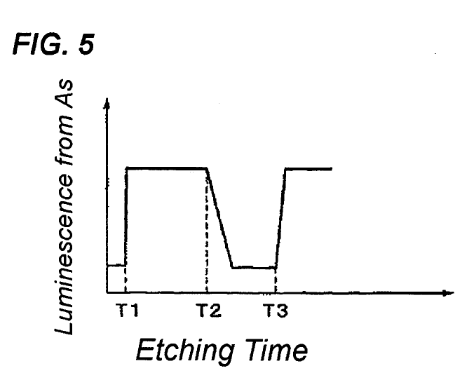

The chamber for the RIE provides the spectrometer to detect the luminescence of the plasma during the etching and to analyze the spectrum of the luminescence. Detecting the luminescence of arsenic (As), which is the wavelength of 194 nm, the etching process may be precisely controlled. FIG. 5 shows a behavior of the luminescence intensity from arsenic, where T1 denotes the beginning of the etching, while T3 is the termination of the etching. At the beginning, because the RIE process etches the second upper SCH layer that includes arsenic, the luminescence from arsenic may be detected. However, the luminescence intensity of arsenic drastically decreases at the instant T2 when the etching reaches the monitoring layer 22 that does not include arsenic. Forwarding the etching further, the luminescent from arsenic appears again at the instant T3 when the first upper SCH layer 20 exposes because the first upper SCH layer 20 is made of GaInAsP including arsenic. To terminate the etching at the instant T3, the height or the depth of the mesa in the diffraction grating may be precisely determined by the total thickness, t1+t2, of the monitoring layer 22 and the second upper SCH layer 24.

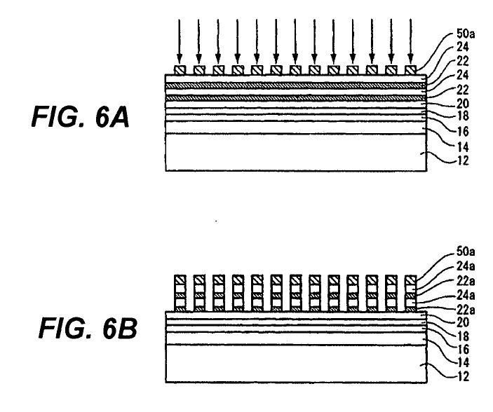

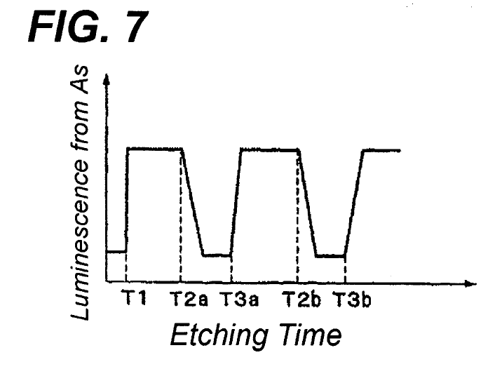

In an alternative, the process may detect the luminescence from phosphorous (P), which is 253 nm slightly longer than that of arsenic, or may detect the luminescence from both phosphorous and arsenic. Because the monitoring layer 22 and the second upper SCH layer 24 both include phosphorous, the process is necessary to distinguish these two layers by comparing the luminescence intensity of respective layers. Moreover, in the latter process, where the luminescence from both of arsenic and phosphorous is detected, the instant T2 when the etching of the monitoring layer 22 begins may be further precisely detected because the increase of the luminescence intensity of phosphorous and the decrease of the luminescence intensity of arsenic are simultaneously detectable. In a still another modification, the luminescence from gallium, which is 417 nm, may be detected in stead of that from arsenic. For the monitoring layer 22, it may be preferable to stack GaInAsP layers and InP layers alternately, as shown in FIG. 6. FIG. 7 illustrates a behavior of the luminescence intensity. As shown in FIG. 7, to monitor the luminescence from arsenic during the etching enables to evaluate the etching rate of the second upper SCH layer 24 made of GaInAsP in addition to determine the termination of the etching.

After the etching of the upper SCH layer and the monitoring layer, the first p-type InP upper cladding layer 28 fills the gaps between the mesas made of the upper SCH layer 24 and the monitoring layer 22. The first p-type InP layer 28 fully buries the diffraction grating 26.

Similar to the formation of the insulating mask 50 for the diffraction grating, on the p-type upper cladding layer 28 is formed with another insulating mask to form the stripe mesa structure. This insulating mask may be made of silicon oxide (SiO₂) and silicon nitride (SiN). A wet-etching may form the stripe mesa with a width of about 1.5 μm at a portion of the MQW active layer 18. This stripe mesa includes the first p-type InP cladding layer 28, the diffraction grating 26 constituted by the second upper SCH layer 24 and the monitoring layer 22, the first upper SCH layer 20, the MQW active layer 18, the lower SCH layer 16 and an upper portion of the n-type InP buffer layer 14. Subsequently, the process selectively grows, with the conventional OMVPE technique, the current blocking portion including the p-type InP layer 36 and then-type InP layer in both sides of the mesa stripe so as to bury the stripe as leaving the insulating mask.

Finally, on the mesa stripe and on the current blocking portion are grown with the p-type InP layer, which is the second upper cladding layer, and the p-type InGaAs contact layer 32 after removing the insulating mask. On the p-type InGaAs layer is fully covered with the other insulating film 34, which is often called as a passivation film, made of silicon oxide (SiO₂) or silicon nitride (SiN) except for an opening where the electrode is processed. The passivation film made of SiN is preferable from the viewpoint of the block of the device from the moisture. The p-type electrode made of stacked metals of Ti/Pt/Au is evaporated on the p-type InGaAs contact layer exposed from the opening in the passivation film 34, while, the back surface of the substrate 12 is alloyed with an eutectic metal of AuGeNi. Thus, the DFB-LD according to the present invention is completed.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

I claim:

1. A process to form a diffraction grating by a semiconductor material, comprising steps of:
(a) sequentially growing at least one monitoring layer and at least one semiconductor layer, the at leas one monitoring layer and the at least one semiconductor layer being made of group III-V compound semiconductor materials, one of the monitoring layer and the semiconductor layer containing arsenic (As) and the other of the monitoring layer and the semiconductor layer not containing arsenic (As);
(b) forming an etching mask made of inorganic material containing silicon, the etching mask having a stripe with a specific period; and
(c) dry-etching the semiconductor layer and the monitoring layer sequentially based on the etching mask with the specific period to form the diffraction grating,
wherein the dry-etching is carried out as monitoring a luminescence from arsenic (As).

2. The process according to claim 1,
wherein the monitoring layer is made of InP and the semiconductor layer is made of InGaAsP.

3. The process according to claim 1,
wherein the step of sequentially growing includes a step of growing a plurality of monitoring layers and a plurality of semiconductor layers alternately to each other, and
wherein the step of dry-etching includes a step for etching the plurality of monitoring layers and the plurality of semiconductor layers sequentially.

4. A process to form a diffraction grating made of semiconductor materials, comprising steps of:
(a) sequentially growing a monitoring layer and at least a semiconductor layer on a semiconductor substrate, the monitoring layer being made of a first III-V compound semiconductor material containing an element and the semiconductor layer being made of a second III-V compound semiconductor material not containing the element;
(b) forming an etching mask made of inorganic material containing silicon, the etching mask having a stripe with a specific period; and
(c) dry-etching the semiconductor layer and the monitoring layer sequentially based on the etching mask with the specific period to form the diffraction grating,
wherein the dry-etching is carried out as monitoring a luminescence from the element contained in the monitoring layer and not contained in the semiconductor layer.

5. The process according to claim 4,
wherein the monitoring layer is made of InP and the semiconductor layer is made of InGaAsP, and
wherein the dry-etching is carried out as monitoring the luminescence form one of gallium (Ga) and arsenic (As).

6. A distributed feedback laser diode, comprising:
a semiconductor substrate made of InP;
an active layer with a multi-quantum well structure;
a monitoring layer made of a first compound semiconductor material;
a first upper SCH layer; and
a second upper SCH layer provided on the monitoring layer to form a periodic stripe with a plurality of mesas, the second upper SCH layer being made of second compound semiconductor material, the first upper SCH layer filling gaps between the mesas to form a diffraction grating,
wherein the second compound semiconductor material contains at least an element not contained in the first compound semiconductor material.

7. The distributed feedback layer diode according to claim 6,
wherein the first compound semiconductor material is InP and the second compound semiconductor material is GaInAsP.
